(19) United States
(12) Patent Application Publication
(10) Pub. No.: US 2013/0140967 A1
(43) Pub. Date: Jun. 6, 2013

(54) HOUSING OF ELECTRONIC DEVICE AND METHOD FOR MANUFACTURING SAME

(71) Applicants: JU-PING DUAN, Shenzhen City (CN); MING-FU LUO, Shenzhen City (CN)

(72) Inventors: JU-PING DUAN, Shenzhen City (CN); MING-FU LUO, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/556,430

(22) Filed: Jul. 24, 2012

(30) Foreign Application Priority Data
Dec. 2, 2011 (CN) 201110395124.0

(51) Int. Cl. H05K 5/02; B23P 11/00

(52) U.S. Cl. 312/223.1; 29/592.1

(57) ABSTRACT

A housing of an electronic device includes a main body, at least one sidewall, and a strengthening portion. The sidewall bends outward from an edge of the main body. The sidewall includes an inner side surface adjacent to the main body and an outer side surface opposite to the inner side surface. The strengthening portion is located on the inner side surface of the at least one sidewall. The sidewall defines a connecting port at the outer side surface thereof, and the connecting port passes through the at least one sidewall and the strengthening portion. The present disclosure further provides a manufacturing method of the housing.

### BACKGROUND

1. Technical Field

The present disclosure relates to a housing, particularly to a housing of an electronic device and a method for manufacturing the housing.

2. Description of Related Art

A housing of an electronic device defines a plurality of connecting ports at a sidewall thereof, for connecting with another electronic device to exchange data. Electronic devices are becoming thinner and thinner. This reduces the overall capability of being contained or containable in the sidewall of the housing, and the sidewall of the housing is easily deformed when in use. In addition, the connecting ports may be deformed, which affects the appearance of the electronic device and possibly its performance.

Therefore, there is room for improvement in the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout several views, and all the views are schematic.

FIG. 1 is a partial, isometric view of an embodiment of a housing of an electronic device.

FIG. 2 is an enlarged, isometric view of a circled portion II shown in FIG. 1.

FIG. 3 is a cross-section view taken along line III-III shown in FIG. 1.

FIG. 4 is a flow chart of an embodiment of a manufacturing method of the housing shown in FIG. 1.

### DETAILED DESCRIPTION

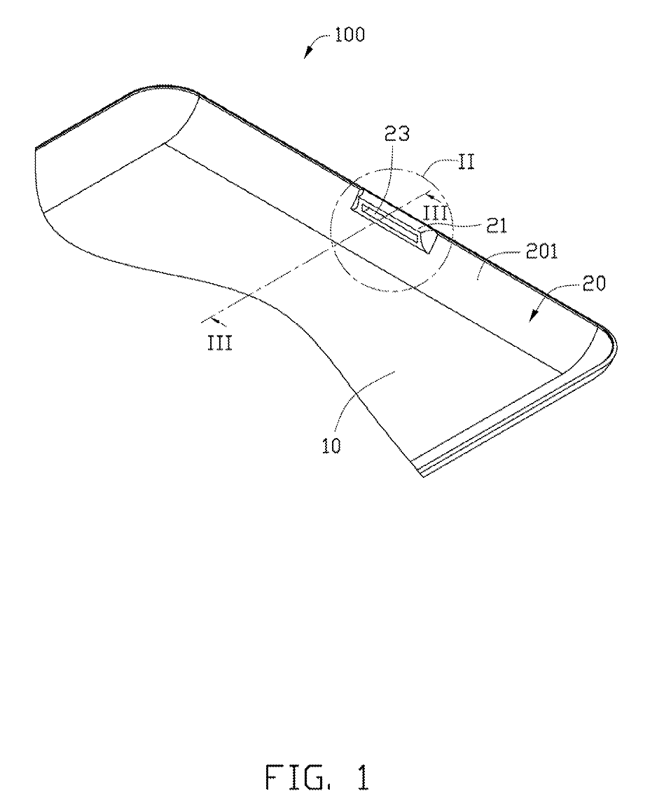

FIG. 1 shows an embodiment of a housing 100 (only shown in a partial isometric view) including a main body 10 and at least one sidewall 20. The sidewall 20 may curve upwards or downwards from an edge of the main body 10. In the illustrated embodiment, there are four sidewalls 20, and the four sidewalls 20 are connected end to end, respectively. The housing 100 is for an electronic device (not shown).

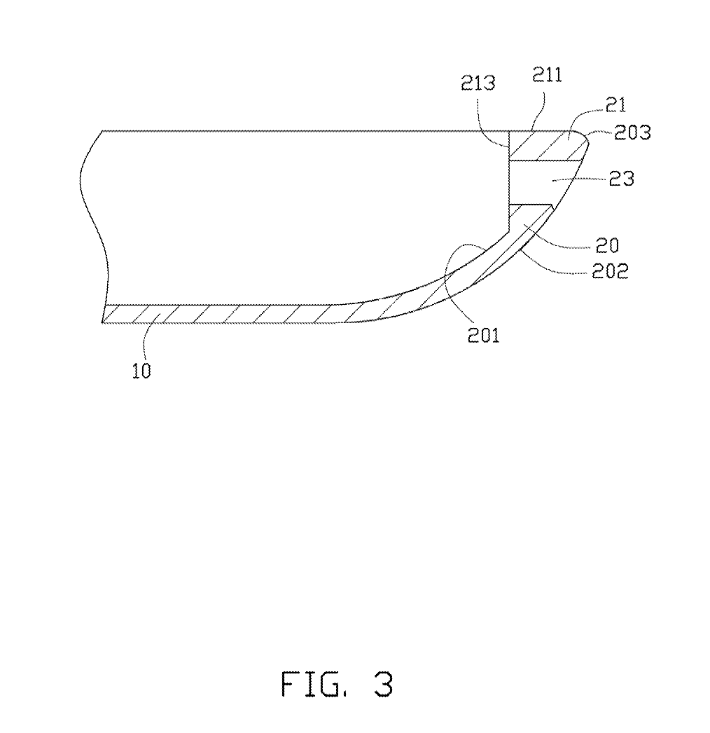

Referring to FIG. 3, the main body 10 is substantially a plate, and the sidewalls 20 are substantially a plurality of arcuate sheets. The housing 100 is made of one or more metallic materials. The main body 10 and the sidewalls 20 are pressed or milled from an integrated base material (not shown). In the illustrated embodiment, the housing 100 is made of aluminum.

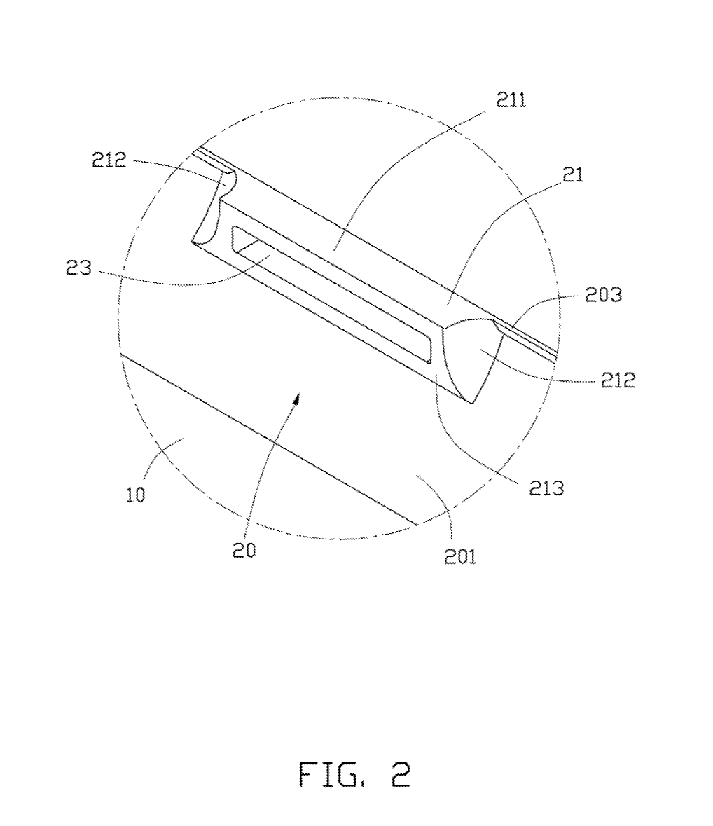

FIGS. 2 and 3 show one of the sidewalls 20 at an end of the main body 10 including an inner side surface 201, an outer side surface 202 opposite to the inner side surface 201 and a connecting edge 203 connecting the inner side surface 201 and the outer side surface 202. The inner side surface 201 and the outer side surface 202 are substantially arcuate surfaces, with a constant thickness of metallic material between them. The connecting edge 203 is substantially arcuate stripe, configured for engaging with one or more electronic components (not shown) of the electronic device, such as a screen fixing frame (not shown), for example. The housing further includes a strengthening portion 21 located at an end of the inner side surface 201 away from the main body 10. The sidewall 20 defines a connecting port 23 at the outer side surface 202. The connecting port 23 passes through the sidewall 20 and the strengthening portion 21, to allow the insertion of a connecting male port, for example.

The strengthening portion 21 includes a first surface 211, a pair of second surfaces 212, and a third surface 213. The first surface 211 connects with the connecting edge 203. The third surface 213 defines an included angle relative to the inner side surface 201, and connects with the first surface 211. The pair of second surfaces 212 are arranged at opposite ends of the first surface 211 and the third surface 213. The connecting port 23 passes through the third surface 213. In the illustrated embodiment, the first surface 211 is flush with the connecting edge 203. The first surface 211 and the third surface 213 are a plurality of planar surfaces, and perpendicular to each other. The third surface 213 is perpendicular to the main body 10. The second surfaces 212 are arcuate. In other embodiments, the second surfaces 212 can be planar, for ease of manufacture. The first surface 211 may be inclined relative to the third surface 213. The third surface 213 may be inclined relative to the main body 10.

The connecting port 23 is substantially a rectangular hole, and the connecting port 23 passes through the outer side surface 202 and the third surface 213. In other embodiments, the connecting port 23 can be other shapes, such as trapezoidal or circular, for example. The number of the connecting ports 23 can be two, or three or more, and the number of the strengthening portion 21 may be two, or three or more according to the number of the connecting portions 23. In the illustrated embodiment, the strengthening portion 21 is integrated with the sidewall 20, and the strengthening portion 21 is manufactured via pressing or milling. In other embodiments, the strengthening portion 21 may be mounted on the sidewall 20 via adhesive, fastenings or welding, for example; and the connecting port 23 also passes through the sidewall 20 and the strengthening portion 21. The electronic components can be fixed inside the housing 100 via any means.

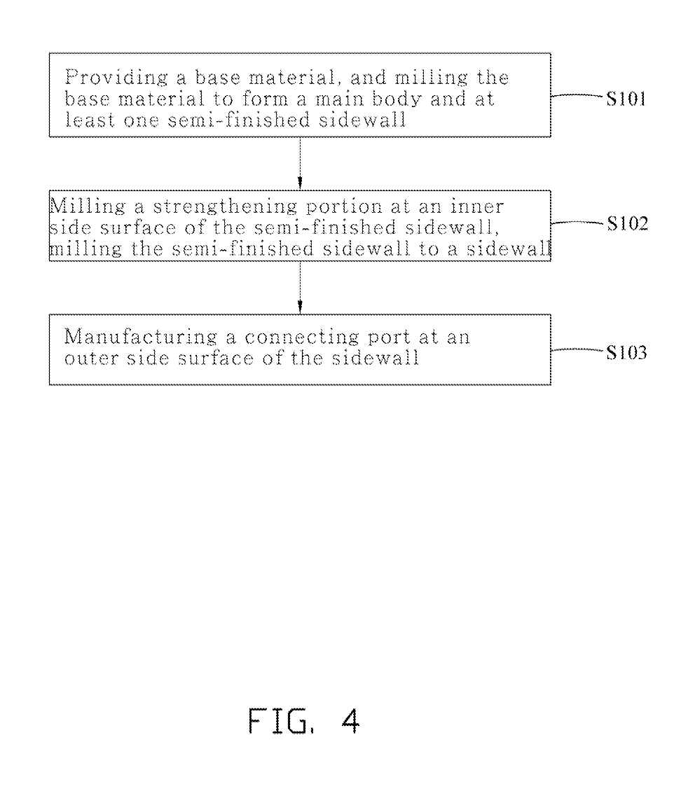

FIG. 4 shows a flow chart of a method for manufacturing the housing 100 illustrated as follows.

In step S101, a metallic base material (not shown) is provided, and the metallic base material is milled to form a main body 10 and at least one (semi-processed) semi-finished sidewall (not shown). The semi-finished or semi-processed sidewall bends outward from an edge of the main body 10. The main body 10 is substantially a plate, and the sidewalls 20 are substantially arcuate sheets. In the illustrated embodiment, the metallic base material is further milled to form at least one sidewall 20. There are three sidewalls 20 and one semi-finished sidewall. The thickness of the semi-finished sidewall is greater than that of the sidewalls 20.

In step S102, a strengthening portion 21 is milled at an inner side surface of the semi-finished sidewall, and the semi-finished sidewall is milled to become a sidewall 20 (finished state). In the illustrated embodiment, the strengthening portion 21 is positioned at an end of the inner side surface 201 away from the main body 10. The sidewall 20 supporting the strengthening portion 21 is located at an end of the main body 10.

In step S103, a connecting port 23 is manufactured at an outer side surface 202 of the sidewall 20, and the connecting port 23 passes through the sidewall 20 and the strengthening portion 21. In the illustrated embodiment, the connecting port 23 is manufactured by milling. The connecting port 23 is substantially a rectangular hole. In other embodiments, the connecting port 23 can be other shapes, such as trapezoidal or circular, for example.

The strengthening portion 21 prevents the sidewall 20 from deforming when a connecting male port, for example, is inserted into and through the strengthening portion 21 because of the presence of the connecting port 23 that is providing passage of the connecting male port through the strengthening portion 21. The depth of the connecting port 23 is configured such that the wires of the connecting male port are able to be prevented from being cut or frayed by the sidewalls (not labeled) of the connecting port 23.

It is believed that the present embodiments and their advantages will be understood from the foregoing description, and it will be apparent that various changes may be made thereto without departing from the spirit and scope of the embodiments or sacrificing all of its material advantages.

What is claimed is:

1. A housing, for an electronic device, comprising:
a main body;
at least one sidewall curving from an edge of the main body, the at least one sidewall comprising an inner side surface adjacent to the main body and an outer side surface opposite to the inner side surface; and
a strengthening portion formed on the inner side surface of the at least one sidewall, wherein the at least one sidewall defines a connecting port at the outer side surface, and the connecting port passes through the at least one sidewall and the strengthening portion.

2. The housing of claim 1, wherein the inner side surface and the outer side surface are a plurality of arcuate surfaces, with a constant thickness of metallic material between the inner side surface and the outer side surface .

3. The housing of claim 1, wherein the at least one sidewall further comprises a connecting edge connecting the inner side surface and the outer side surface, the connecting edge is substantially an arcuate stripe, configured for engaging with one or more electronic components of the electronic device.

4. The housing of claim 3, wherein the strengthening portion comprises a first surface, a pair of second surface, and a third surface, the first surface connects with the connecting edge, the third surface defines an included angle relative to the inner side surface, and connects with the first surface, the pair of second surfaces are arrange at the opposite ends of the first surface and the third surface, and the connecting port passes through the third surface.

5. The housing of claim 4, wherein the first surface is perpendicular to the third surface.

6. The housing of claim 4, wherein the third surface is perpendicular to the main body.

7. The housing of claim 4, wherein the first surface is inclined relative to the third surface, the third surface is inclined relative to the main body.

8. The housing of claim 4, wherein the first surface is flush with the connecting edge.

9. A method for manufacturing the housing of claim 1, comprising:
providing a base material, and milling the base material to form a main body and at least one semi-finished sidewall curving from an edge of the main body;
milling a strengthening portion at an inner side surface of the at least one semi-finished sidewall, and milling the at least one semi-finished sidewall to form at least one sidewall;
manufacturing a connecting port at an outer side surface of the at least one sidewall, and the connecting port passes through the at least one sidewall and the strengthening portion.

10. The manufacturing method of the housing of claim 9, wherein the connecting port is manufactured by milling.

11. The manufacturing method of the housing of claim 9, wherein the metallic base material is further milled to form at least one sidewall.

12. The manufacturing method of the housing of claim 9, wherein the thickness of the semi-finished sidewall is greater than the that of the sidewalls.

13. The manufacturing method of the housing of claim 9, wherein the at least one sidewall further comprises a connecting edge connecting the inner side surface and the outer side surface, the connecting edge is substantially an arcuate stripe, configured for engaging with one or more electronic components of the electronic device.

14. The manufacturing method of the housing of claim 13, wherein the strengthening portion comprises a first surface, a pair of second surface, and a third surface, the first surface connects with the connecting edge, the third surface defines an included angle relative to the inner side surface, and connects with the first surface, the pair of second surfaces are arrange at the opposite ends of the first surface and the third surface, the connecting port passes through the third surface.
